(19) United States
(12) Patent Application Publication
(10) Pub. No.: US 2025/0351278 A1
(43) Pub. Date: Nov. 13, 2025

(54) ZONAL CONTROLLER PACKAGING

(71) Applicant: Rivian IP Holdings, LLC, Irvine, CA (US)

(72) Inventors: Kevin GIANNINI, Costa Mesa, CA (US); Kyle ROBERTSON, Morgan Hill, CA (US)

(21) Appl. No.: 19/071,607

(22) Filed: Mar. 5, 2025

Related U.S. Application Data
(60) Provisional application No. 63/643,429, filed on May 7, 2024.

(51) Int. Cl. H05K 5/00; B60R 16/033; H05K 7/20

(52) U.S. Cl. CPC H05K 5/0047; B60R 16/033; H05K 5/0069; H05K 7/20472

(57) ABSTRACT

An electronic control unit (ECU) for zonal power distribution in a vehicle includes a housing assembly that may include a top cover with sealed power terminals and connector headers, a printed circuit board assembly (PCBA), and a base cover that functions as a heat sink. The ECU may be positioned in different zones of the vehicle, including exterior locations, and may provide redundant power distribution through multiple power sources including a DC-DC converter and a low voltage battery. The zonal architecture may allow for diversified installation of ECUs and provides fault isolation capabilities, enabling critical vehicle functions to remain operational in the event of a power source failure. The ECU housing assembly may include thermal management features and various sealing mechanisms that may protect against environmental conditions.

### CROSS REFERENCE TO RELATED APPLICATION(S)

The present application claims the benefit of U.S. Provisional Application No. 63/643,429, entitled “ZONAL CONTROLLER PACKAGING”, filed May 7, 2024, the entirety of which is incorporated herein for reference.

### INTRODUCTION

This application is directed to zonal architecture for functional and power distribution and packaging thereof, and more particularly, associated with an electric vehicle.

### SUMMARY

The disclosed subject matter provides for zonal architecture for power distribution and packaging thereof that may allow for diversified installation of electric control units.

### BRIEF DESCRIPTION OF THE DRAWINGS

Certain features of the subject technology are set forth in the appended claims. However, for purpose of explanation, several embodiments of the subject technology are set forth in the following figures.

FIG. 1A illustrates an exemplary overhead view of a vehicle with zonal power distribution as described herein.

FIG. 1B illustrates an exemplary side view of a vehicle with zonal power distribution as described herein.

FIG. 1C illustrates an exemplary block diagram of a system with zonal power distribution as described herein.

FIG. 2A illustrates an exemplary perspective view of top cover of electronic control unit (ECU).

FIG. 2B illustrates an exemplary perspective view of printed circuit board assembly (PCBA) of an ECU.

FIG. 2C illustrates an exemplary perspective view of bottom cover of an ECU.

FIG. 2D illustrates an overhead view of bottom cover of an ECU.

FIG. 3A illustrates an exemplary perspective view of top cover of ECU.

FIG. 3B illustrates an exemplary perspective view of printed circuit board assembly (PCBA) of an ECU.

FIG. 3C illustrates an exemplary perspective view of bottom cover of an ECU.

FIG. 3D illustrates an overhead view of bottom cover of an ECU.

FIG. 4A illustrates an exemplary perspective view of top cover of ECU.

FIG. 4B illustrates an exemplary perspective view of printed circuit board assembly (PCBA) of an ECU.

FIG. 4C illustrates an exemplary perspective view of bottom cover of an ECU.

FIG. 4D illustrates an overhead view of top cover of an ECU.

FIG. 4E illustrates an exemplary overhead view of a top cover.

FIG. 4F illustrates an exemplary first side view of a top cover.

FIG. 4G illustrates an exemplary second side view of a top cover.

FIG. 4H illustrates an exemplary top view of terminals openings.

FIG. 4I illustrates an exemplary overhead view of FIG. 4C.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

The disclosed subject matter provides for a zonal architecture for power distribution and circuit design thereof that allows for redundancy in power distribution and therefore may protect against the loss of one or more power buses or electronic control units (ECUs). The ECU functions of the zonal architecture may be based on geographic zone of a vehicle, such as front left, front right, or rear zone. In addition, there may be two or more power sources for low voltage power distribution. In an example, each ECU may be provided continuous power from direct current to direct current converter (DCDC) wherein the DCDC steps down from a high voltage battery pack and may be provide power from a low voltage (LV) battery (e.g., 12V battery). As further described herein, if there is a fault on a first power source (e.g., DCDC bus), then a second power source (e.g., LV battery bus) may power the vehicle to operate one or more functions, which may be functions associated with critical tasks. For example, the advanced driver assistance system (ADAS) system of the vehicle may continue to be powered to keep the vehicle moving appropriately until a user takes over. In addition, there may be redundant functions for each ECU, therefore, if a first ECU fails, a second ECU may continue to operate the redundant functions or other ECU specific functions.

The disclosed subject matter provides for packaging of electronic control units that may be different based on the position (e.g., zone). The disclosed packaging allows for ECUs to be placed inside the vehicle or on the exterior of the vehicle (e.g., near a spare tire bin area or underbody of vehicle), which may allow for the use of less harnesses, ease of maintenance access, or provide for reduced cost. For example, the disclosed ECU packaging may be IP67 rated waterproof for flexible exterior positioning.

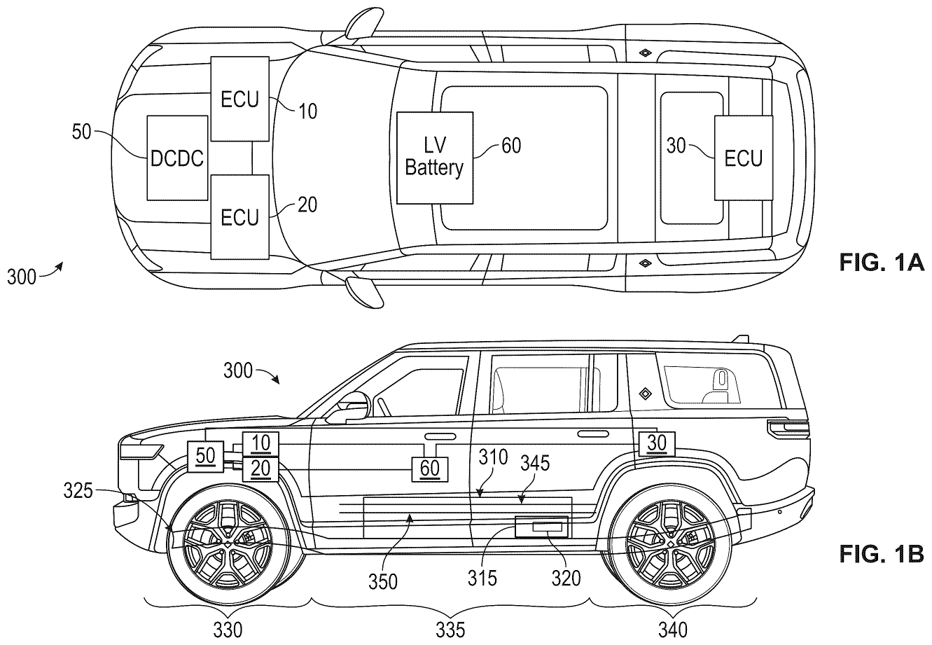

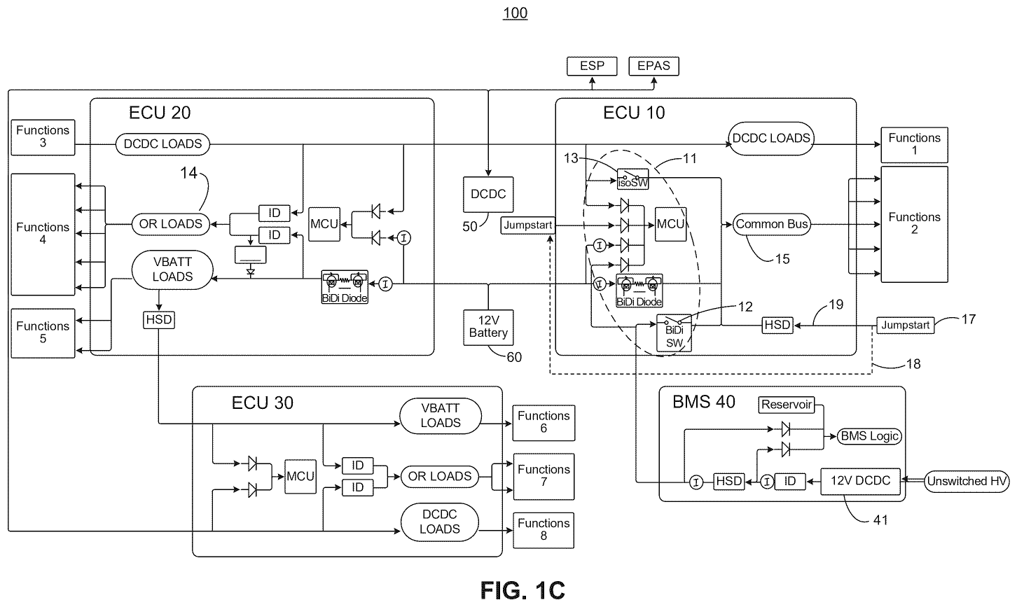

FIG. 1A illustrates an exemplary overhead view of vehicle 300. As further described herein, vehicle 300 may include electronic control units (ECUs) in front portion 330 of vehicle 300 (e.g., ECU 10 and ECU 20), an ECU in rear portion 340 of vehicle 300 (e.g., ECU 30), direct current to direct current converter (DCDC) 50, low voltage (LV) battery 60 (e.g., approximately 11V-14V battery), or jumpstart access 17, among other things.

FIG. 1B illustrates an exemplary side view of vehicle 300. As shown, the vehicle 300 may include one or more battery packs, such as high voltage (HV) battery pack 310 (e.g., 450V), which may be located near the center body portion 335 of vehicle 300. HV battery pack 310 may be coupled with one or more electrical systems of the vehicle 300 to provide power to the electrical systems. As further described herein, ECU 10, ECU 20, or ECU 30 may be communicatively connected with or have power distributed with each other and may be functionally redundant for power or other operations of electronic components of vehicle 300.

In one or more implementations, the vehicle 300 may be an electric vehicle having one or more electric motors that drive the wheels 302 of the vehicle using electric power from HV battery pack 310. In one or more implementations, the vehicle 300 may also, or alternatively, include one or more chemically-powered engines, such as a gas-powered engine or a fuel cell powered motor. For example, electric vehicles can be fully electric or partially electric (e.g., hybrid or plug-in hybrid). In various implementations, the vehicle 300 may be a fully autonomous vehicle that can navigate roadways without a human operator or driver, a partially autonomous vehicle that can navigate some roadways without a human operator or driver or that can navigate roadways with the supervision of a human operator, may be an unmanned vehicle that can navigate roadways or other pathways without any human occupants, or may be a human operated (non-autonomous) vehicle configured for a human operator.

In the example of FIG. 1B, the vehicle 300 may be implemented as a truck (e.g., a pickup truck) having a battery pack 310. As shown, HV battery pack 310 may include on or more battery modules 315, which may include one or more battery cells 320. However, this is merely illustrative and, in other implementations, HV battery pack 310 may be provided without any battery modules 315 (e.g., in a cell-to-pack configuration).

As shown in FIG. 1B, the vehicle 300 may include a support structure such as a chassis 325 (e.g., a frame, internal frame, or other support structure). The chassis 325 may support various components of the vehicle 300. As shown, the chassis 325 may span a front portion 330 (e.g., a hood or bonnet portion), center body portion 335, and a rear portion 340 (e.g., a trunk, payload, or boot portion) of the vehicle 300 in some implementations. In one or more implementations, HV battery pack 310 may be installed on the chassis 325 (e.g., within one or more of the front portion 330, center body portion 335, or the rear portion 340). As shown, HV battery pack 310 may include or be electrically coupled with one or more one busbars (e.g., one or more current collector elements). In the example of FIG. 1B, the vehicle 300 includes a first busbar 345 and a second busbar 350, either or both of which may include electrically conductive material to connect or otherwise electrically couple the battery module(s) 315 or the battery cell(s) s 320 with other electrical components of the vehicle 300 to provide electrical power to various systems or components of the vehicle 300.

In other implementations, the vehicle 300 may implemented as another type of electric truck, an electric delivery van, an electric automobile, an electric car, an electric motorcycle, an electric scooter, an electric passenger vehicle, an electric passenger or commercial truck, a hybrid vehicle, or other vehicles such as sea or air transport vehicles, planes, helicopters, submarines, boats, or drones, and/or any other movable apparatus having a battery pack 310 (e.g., that powers the propulsion or drive components of the moveable apparatus).

FIG. 1C illustrates an exemplary block diagram of system 100 that may include a plurality of ECUs of vehicle 300. An ECU is an embedded system that may control one or more of the electrical systems or subsystems in a vehicle. The positioning and connections of ECU 10, ECU 20, or ECU 30 may provide for a level of redundancy for faults, which may be caused by collisions or other malfunctions. The design of system 100 may allow vehicle 300 to safely operate for a period after the fault, such as being able to drive vehicle 300 (e.g., steer, brake, or accelerate) to a safe position off of a roadway or being able to operate electronic controlled functions (e.g., door latches) of vehicle 300, among other things. As shown, ECU 10, ECU 20, and ECU 30 may be connected with DCDC 50 (also referred herein as DCDC bus 50) to operate DCDC loads and a low voltage (LV) battery 60 (e.g., 12V battery or LV battery bus 60) to operate LV battery loads. In an example, one or more ECUs (e.g., ECU 10) may include a fault isolation system 11. Fault isolation system 11 may include isolation switch or a bidirectional (Bidi) switch 12. In some configurations, in consideration of safety, only one ECU (e.g., ECU 10) may include fault isolation system 11. As shown, ECU 10 may include a common bus 15, which may operate slightly differently than other buses (e.g., OR load bus 14), as the common bus may allow for bidirectional power to be transmitted to and from LV battery 60 that may be a function of using fault isolation system 11. The common bus (specific to ECU 10) allows power to flow bidirectionally, from LV battery 60 to DCDC 50, or from DCDC 50 to LV battery 60. The OR bus does not allow power to flow bidirectionally (it does not connect or isolate LV battery 60 and DCDC 50 networks). The other element, which is a shared attribute of both common bus and OR Bus, that in the event of a failure of the DCDC 50 or LV battery 60, the common bus (or OR Bus) will retain operation (e.g., will be available).

With continued reference to FIG. 1C, each ECU may have on or more dedicated functions that may be powered by DCDC 50, LV battery 60, or LV DCDC 41. ECU 10 may operate functions 1, functions 2, and jumpstart functions. ECU 10 may be connected with jumpstart access 17 (e.g., wiring located in a rear portion 340 of vehicle 300). Jumpstart access 17 may allow an external power source (e.g., jumpstart pack) to connect with ECU 10 in order to jumpstart electronic functions of the vehicle, particularly when LV battery 60 is depleted. As further described herein, jumpstart access 17 may have multiple routes that include jumpstart route 18 (e.g., to microcontroller) and jumpstart route 19 (e.g., to Bidi switch 12). Functions 1 may include functions such as first row universal serial bus, or electronic stability program (ESP), among other things. Functions 2 may include functions such as right door latch, passenger seat motor, right headlamp, alarm module, or frunk latch, among other things. In this example, functions 1 of ECU 10 may only be powered by DCDC 50, while functions 2 of ECU 10 may be powered by DCDC 50 (which may be the primary power) or LV battery 60 (which may be the secondary power), which may be referred to common bus 15. ECU 10 may be located on the right front of vehicle 300 and therefore may operate functions primarily for the right portion of vehicle 300.

As shown in FIG. 1C, ECU 20 may operate functions 3, functions 4, and functions 5. Functions 3 may include functions such as front suspension valves, or autonomy control module, among other things. Functions 4 may include functions such as steering angle sensor, front wiper motor, left door latches, left headlamp, exterior near field communication (NFC), or on-board diagnostics (OBD) port, among other things. Functions 5 may include functions such as electric power assisted steering (EPAS), charge port door, interior NFC, or electric powered assisted breaking, among other things. In this example, functions 3 of ECU 20 may only be powered by DCDC 50 and functions 5 of ECU 20 may only be powered by LV battery 60. Functions 4 of ECU 20 may be powered by DCDC 50 (which may be the primary power) or LV battery 60 (which may be the secondary power), which may be referred to OR loads 14 (also referred herein as OR load bus 14). ECU 20 may be located on the left front of vehicle 300 and therefore may operate functions primarily for the left portion of vehicle 300.

As shown in FIG. 1C, ECU 30 may operate functions 6, functions 7, and functions 8. Functions 6 may include functions such as license plate lamp. Functions 7 may include functions such as rear vehicle access system sensors, liftgate latch, trailer brake, right lamp rear, or left lamp rear, among other things. Functions 8 may include functions such as right trailer brake lamp, or rear suspension valves, among other things. In this example, functions 8 of ECU 30 may only be powered by DCDC 50 and functions 6 of ECU 30 may only be powered by LV battery 60. Functions 7 of ECU 20 may be powered by DCDC 50 (which may be the primary power) or LV battery 60 (which may be the secondary power). ECU 20 may be located on the left front of vehicle 300 and therefore may operate functions primarily for the left portion of vehicle 300.

System 100 of FIG. 1C may include a battery management system (BMS) 40. BMS 40 may be located at or near HV battery pack 310 of FIG. 1B, which LV DCDC 41 converts the HV DC to a lower voltage, such as 14V. LV DCDC 41 may help reduce the need for LV battery 60 for some operations, such as when vehicle 300 is in standby mode (e.g., parked). It is contemplated that the functions disclosed herein (e.g., functions 1 through functions 8) may be controlled by other ECUs or powered by any of the listed power sources.

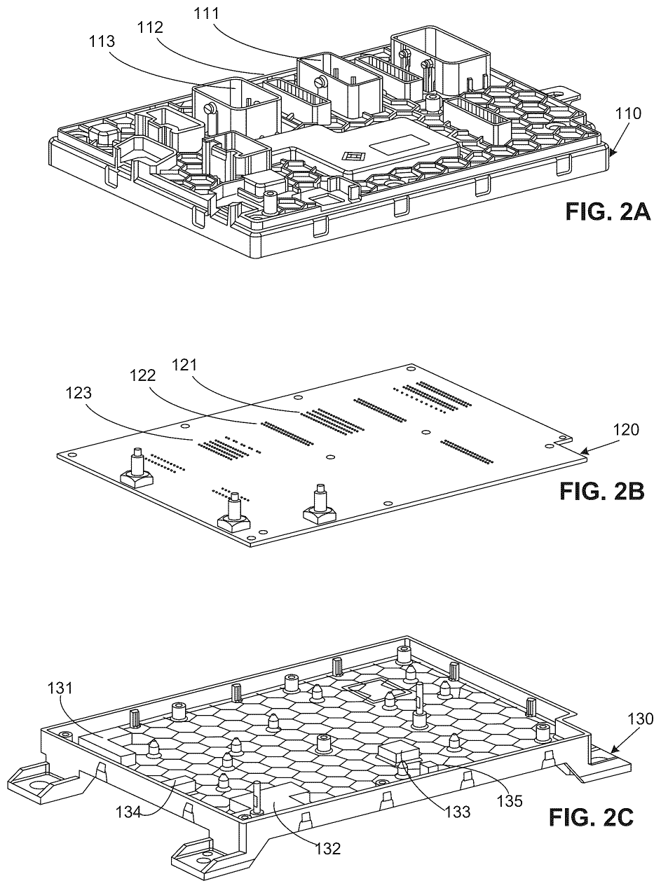

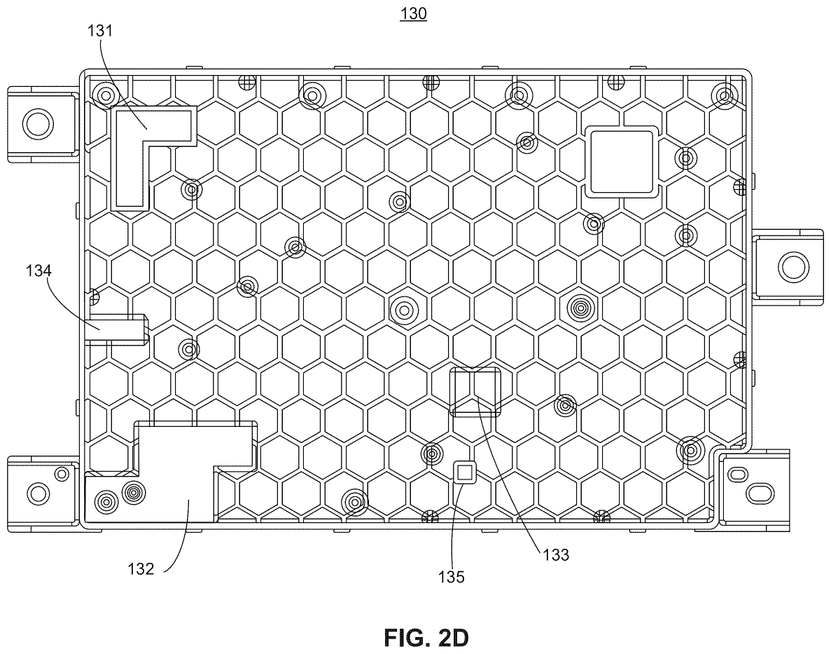

FIG. 2A through FIG. 2C illustrate portions of an exploded perspective view of a physical module of an electronic control unit (ECU), such as ECU 10. FIG. 2A illustrates an exemplary perspective view of top cover 110 of ECU 10. Headers, such as header 111, header 112, or header 113, among others may be molded into top cover 110. Note the shape and positioning of the headers as shown.

FIG. 2B illustrates an exemplary perspective view of printed circuit board assembly (PCBA) 120 of ECU 10. PCBA 120 include stitched press fit pins 121, stitched press fit pins 122, or stitched press fit pins 123, as positioned. Instead of having individual connector headers soldered onto the board, there are stitched press fit pins as shown in FIG. 2B. Headers, in which the cabling/connectors may come through, such as header 111, header 112, or header 113 may be positioned above the stitched press fit pins.

FIG. 2C illustrates an exemplary perspective view of bottom cover 130 of ECU 10. FIG. 2D illustrates an overhead view of bottom cover 130. Bottom cover 130, which may be an aluminum enclosure, may be designed in a way to operate as a heat sink to draw heat from the upper levels (e.g., PCBA 120) for cooling. Area 131, area 132, area 133, area 134, area 135, or the like may be used to heat sink. Note the shape and positioning of the areas. Area 131, area 132, area 132, area 133, area 134, or area 135 may be thermal pads or have thermal putty applied that assist with thermal transfer.

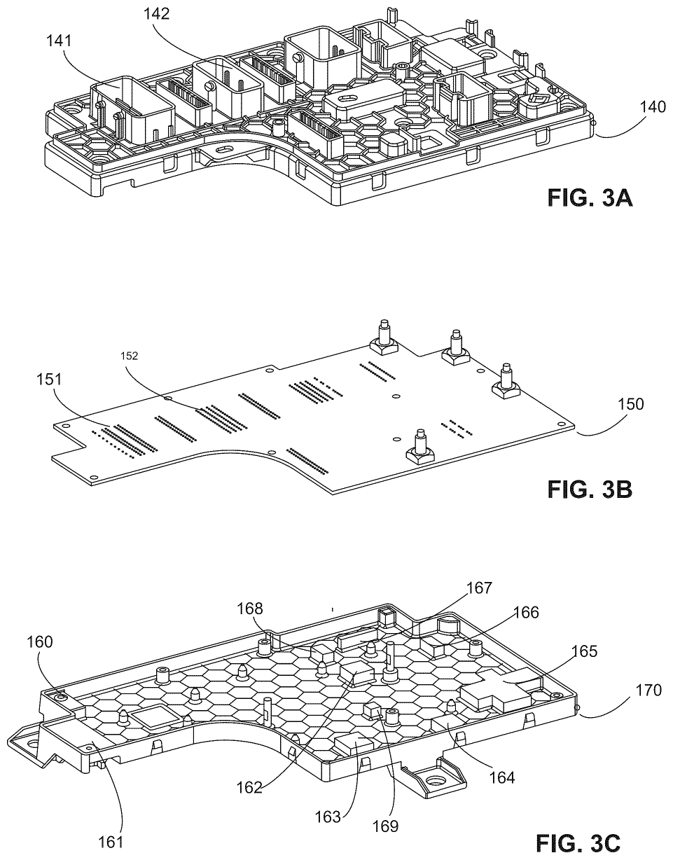

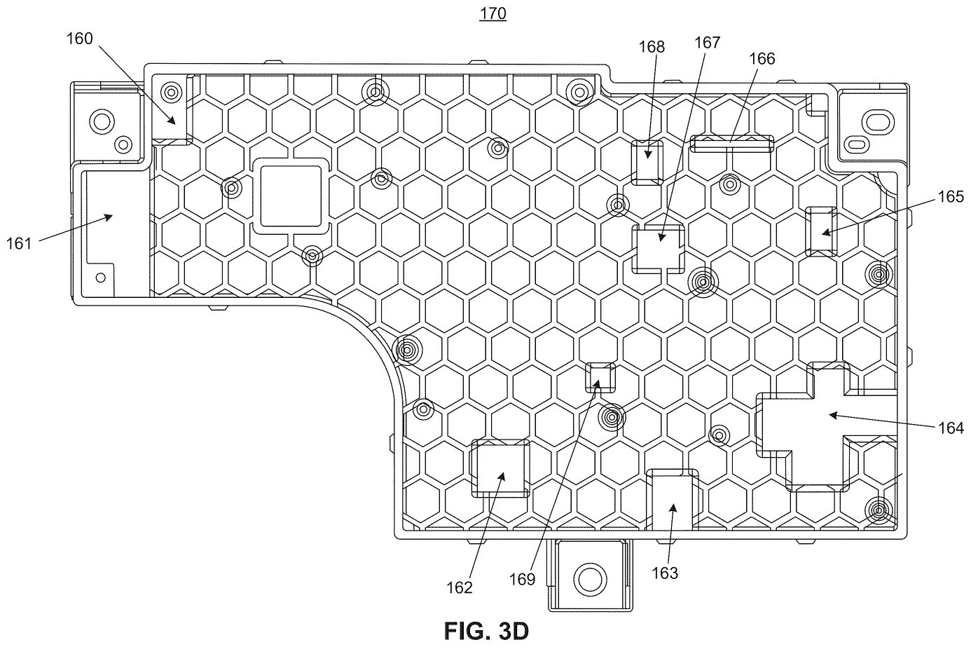

FIG. 3A through FIG. 3C illustrate portions of an exploded perspective view of a physical module of an electronic control unit (ECU), such as ECU 20. FIG. 3A illustrates an exemplary perspective view of top cover 140 of ECU 20. Headers, such as header 141, or header 142, among others may be molded into top cover 140. Note the shape and positioning of the headers as shown.

FIG. 3B illustrates an exemplary perspective view of printed circuit board assembly (PCBA) 150 of ECU 20. PCBA 150 may include stitched press fit pins 151 or stitched press fit pins 152, as positioned. Instead of having individual connector headers soldered onto the board, there are stitched press fit pins as shown in FIG. 3B. Headers, in which the cabling/connectors may come through, such as header 141, or header 142 may be positioned above the stitched press fit pins.

FIG. 3C illustrates an exemplary perspective view of bottom cover 170 of ECU 20. FIG. 3D illustrates an overhead view of bottom cover 170. Bottom cover 170, which may be an aluminum enclosure, may be designed in a way to operate as a heat sink to draw heat from the upper levels (e.g., PCBA 120) for cooling. Area 160 through area 169, or the like may be used to heat sink. Note the shape and positioning of the areas. Area 160 through area 169 may be thermal pads or have thermal putty applied that assist with thermal transfer.

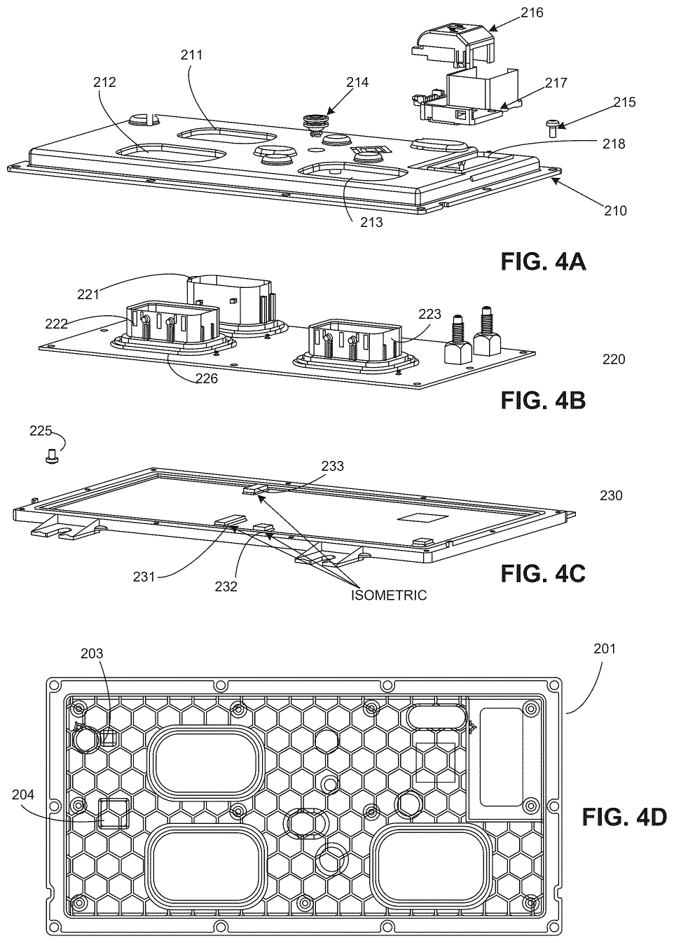

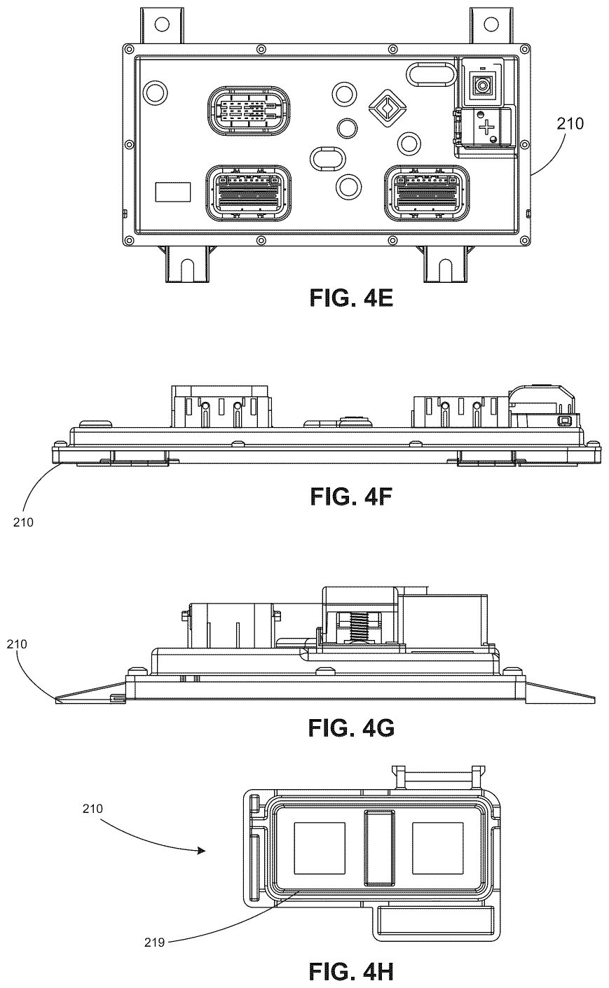

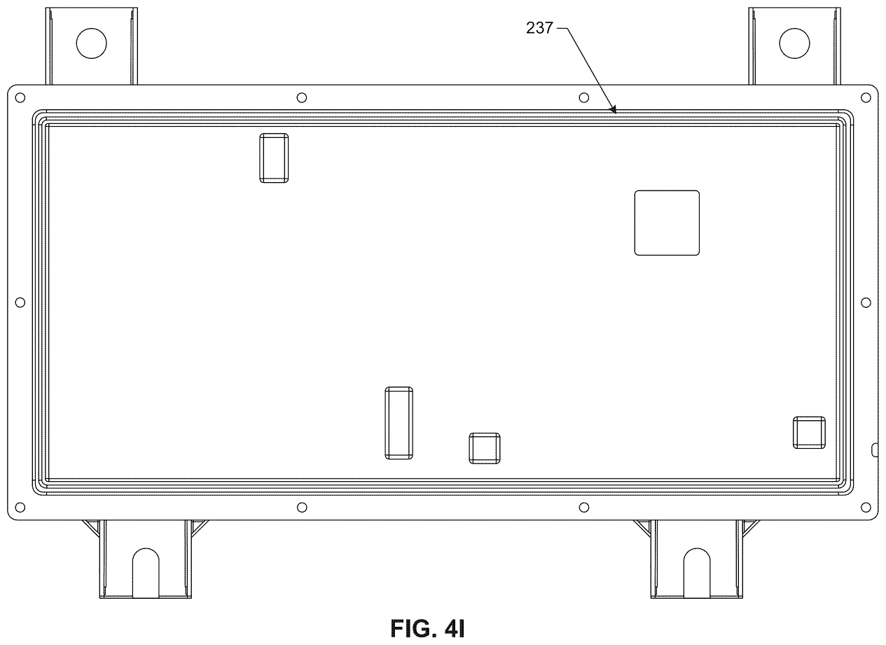

FIG. 4A through FIG. 4C illustrate portions of an exploded perspective view of a physical module of an electronic control unit (ECU), such as ECU 30. FIG. 4A illustrates an illustrates an exemplary perspective view of top cover 210 of ECU 30. Headers openings, such as header opening 211, header opening 212, or header opening 213, among others. Note the shape and positioning of the openings for the headers as shown. Top cover 210 may include pressure relief vent 214, terminal cover 217, terminals opening 218, or power cap 216. FIG. 4D illustrates an exemplary overhead view of top cover 210. FIG. 4F illustrates an exemplary first side view of top cover 210. FIG. 4G illustrates an exemplary second side view of top cover 210. FIG. 4H illustrates an exemplary bottom view of terminals opening 218 in which at groove 219 a gasket (e.g., dispensable gasket) may be placed around terminals.

FIG. 4B illustrates an exemplary perspective view of printed circuit board assembly (PCBA) 220 of ECU 30. PCBA 220 may include individual connector headers, which may be soldered (or otherwise connected) onto the board as shown in FIG. 4B. Headers, in which the cabling/connectors may come through, such as header 221, header 222, or header 223 may be positioned on the pins of PCBA 220. The headers, such as header 222, may have a corresponding gasket (e.g., gasket 226 which may be dispensable). PCBA 220 and top cover 210 may attached together with bolts 225 through corresponding openings in top cover 210. Note the pins may be in place and the whole of each individual connector may be pressed onto the board.

FIG. 4C illustrates an exemplary perspective view of base cover 230 of ECU 30. FIG. 4I is an overhead view of base cover 230. Base cover 230, which may be metal enclosure, may be designed in a way to operate as a heat sink to draw heat from the upper levels (e.g., PCBA 220) for cooling. Area 231 through area 233 may be of different masses and may be used to heat sink. Note the shape and positioning of the areas. Area 231 through area 233 may be thermal pads or have thermal putty applied that assist with thermal transfer. Base cover 230 and top cover 210 may be sealed together with a gasket (e.g., a dispensable gasket) at groove 237 (see FIG. 4I) and attached together with bolt 215 through corresponding openings in base cover 230.

FIG. 4D illustrates an overhead view of zone cover 201, which may be placed on top of top cover 210. Top cover may include area 203 and area 204, which may help act as heat sinks and cool PCBA 220. An additional shield, not shown, may cover ECU 30 to protect against crash impact or unauthorized use. It is contemplated that the features of each ECU disclosed herein may be combined in any given manner.

The methods, systems, or apparatuses disclosed herein may be incorporated into electric vehicles or other devices (e.g., microcontroller unit). The ECU blocks disclosed herein may be distributed with or combined with one or more ECUs or other devices. The zonal controller packaging disclosed herein may be distributed with or combined with one or more zonal controller packaging. The methods, systems, or apparatuses disclosed herein may be incorporated into products, such as various feature specific or zone specific electronic control units (ECUs).

Methods, systems, and apparatus for electronic control units (ECUs) in electric vehicles are disclosed herein. An apparatus may include a top cover comprising power terminals sealed by a gasket, a printed circuit board assembly (PCBA) with connector headers sealed by a gasket, and a base cover attached to the top cover and sealed with a gasket. The apparatus may function as a housing assembly for an ECU of an electric vehicle. The connector headers may be soldered to the PCBA, providing a secure electrical connection. The base cover may act as a heat sink to dissipate thermal energy generated by the electronic components. Additionally, the top cover may include a pressure vent to regulate internal pressure. All combinations (including the removal or addition of steps) in this paragraph and the above paragraphs are contemplated in a manner that is consistent with the other portions of the detailed description.

The apparatus may be designed for durability and environmental protection. It may be located on the undercarriage of a vehicle, exposing it to harsh conditions. To withstand these conditions, the apparatus may be constructed to be waterproof. The base cover may comprise an aluminum enclosure, offering strength and excellent heat dissipation properties. Thermal pads may be incorporated into the base cover to enhance thermal transfer from the electronic components to the heat sink. All combinations (including the removal or addition of steps) in this paragraph and the above paragraphs are contemplated in a manner that is consistent with the other portions of the detailed description.

Another variation of the apparatus may include a top cover with connector headers, a PCBA, and a base cover that covers the PCBA and attaches to the top cover. In this configuration, the PCBA may utilize press fit pins for component connections. The top cover may feature molded-in headers, integrating the connectors directly into the cover structure. As with the previous variation, this apparatus may include a pressure vent in the top cover and thermal pads in the base cover that are configured to assist with heat dissipation. All combinations (including the removal or addition of steps) in this paragraph and the above paragraphs are contemplated in a manner that is consistent with the other portions of the detailed description.

A system for an electric vehicle may incorporate multiple ECUs arranged in different zones of the vehicle. At least one ECU in this system may include the features described above, such as a top cover with sealed power terminals, a PCBA with sealed connector headers, and a base cover acting as a heat sink. This configuration of ECUs may provide functional redundancy, enhancing the reliability of the vehicle's electronic systems. The ECUs may be strategically placed throughout the vehicle, with some located in the front zone and others in the rear zone. Some ECUs may incorporate a fault isolation system to prevent the spread of electrical faults. Notably, at least one ECU may be designed for placement on an exterior portion of the vehicle, highlighting the robust and weatherproof nature of its construction. All combinations (including the removal or addition of steps) in this paragraph and the above paragraphs are contemplated in a manner that is consistent with the other portions of the detailed description.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. An apparatus comprising:
a top cover, wherein the top cover comprises power terminals sealed by a gasket;
a printed circuit board assembly (PCBA) comprising a gasket to seal connector headers; and
a base cover, the base cover attached with the top cover and sealed with a gasket.

2. The apparatus of claim 1, wherein the apparatus comprises an electronic control unit of an electric vehicle.

3. The apparatus of claim 1, wherein the connector headers are soldered to the PCBA.

4. The apparatus of claim 1, wherein the base cover acts as a heat sink.

5. The apparatus of claim 1, wherein the top cover comprises a pressure vent.

6. The apparatus of claim 1, wherein the apparatus is located on an undercarriage of a vehicle.

7. The apparatus of claim 1, wherein the apparatus is waterproof.

8. The apparatus of claim 1, wherein the base cover comprises an aluminum enclosure.

9. The apparatus of claim 1, wherein the base cover comprises thermal pads to assist with thermal transfer.

10. An apparatus comprising:
top cover, wherein the top cover comprises connector headers;
a printed circuit board assembly (PCBA); and
a base cover that covers the PCBA, the base cover attached with the top cover.

11. The apparatus of claim 10, wherein the PCBA comprises press fit pins.

12. The apparatus of claim 10, wherein the base cover acts as a heat sink.

13. The apparatus of claim 10, wherein the top cover comprises molded-in headers.

14. The apparatus of claim 10, wherein the top cover comprises a pressure vent.

15. The apparatus of claim 10, wherein the base cover comprises thermal pads to assist with thermal transfer.

16. A system for an electric vehicle, comprising:
a plurality of electronic control units (ECUs) arranged in different zones of the vehicle,
wherein at least one ECU of the plurality of ECUs comprises:
a top cover comprising power terminals sealed by a gasket;
a printed circuit board assembly (PCBA) comprising connector headers sealed by a gasket; and
a base cover attached with the top cover and sealed with a gasket, wherein the base cover is configured to act as a heat sink.

17. The system of claim 16, wherein the plurality of ECUs is configured to provide functional redundancy.

18. The system of claim 16, wherein the at least one ECU is located in a front zone of the vehicle and at least one ECU is located in a rear zone of the vehicle.

19. The system of claim 16, wherein the at least one ECU comprises a fault isolation system.

20. The system of claim 16, wherein the at least one ECU is configured to be located on an exterior portion of the vehicle.
